(19) United States
(12) Patent Application Publication
(10) Pub. No.: US 2006/0292500 A1
(43) Pub. Date: Dec. 28, 2006

(54) Cure during rinse to prevent resist collapse

(76) Inventors: Jeanette Roberts, Portland, OR (US); Heidi B. Cao, Portland, OR (US); Wang Yueh, Portland, OR (US)

Correspondence Address: Michael A. Bernadicou;BLAKELY, SOKOLOFF, TAYLOR & ZAFMAN LLP, Seventh Floor, 12400 Wilshire Boulevard, Los Angeles, CA, 90025, US

(21) Appl. No.: 11/165,717

(22) Filed: Jun. 24, 2005

(51) Int. Cl. G03F 7/26

(52) U.S. Cl. 430/322; 430/328

(57) ABSTRACT

Numerous embodiments of a method to increase the mechanical strength of a photoresist structure are described. In one embodiment of the present invention, a photoresist material is dispensed over a substrate to form a photoresist layer. The photoresist material is exposed to a first radiation treatment to define a pattern to be formed on the photoresist layer. A developer solution is applied to the photoresist material to form the pattern and rinsed with a rinse solution to remove the developer solution. The photoresist material is exposed to a second radiation treatment to induce cross-linking.

### FIELD

Embodiments of the present invention relate to photolithography of semiconductor devices, and more particularly, to a method to increase the mechanical strength of photoresist structures.

### BACKGROUND

Manufacture of semiconductor devices typically involves a series of processes in which various layers are deposited and patterned on a substrate (e.g., semiconductor wafer) to form a device of the desired type. Line and space patterns are formed on photoresist layers as part of the process to create microelectronic devices. Smaller critical dimensions (CD) for both lines and spaces allow faster circuitry to be created.

Photolithography is a process that is commonly used to form patterns on the semiconductor wafer. FIG. 1 is a flowchart describing a typical photolithography process. In the photolithography process, a layer of photoresist material is deposited over an underlying layer (formed above a substrate or wafer) that is to be patterned (by a process such as etch or ion implantation). Spin coating is a standard method to apply the photoresist material. The coated substrate is then subjected to a baking process (also referred to as post-apply bake) to remove residual solvent from the spin coating process and relieve stresses caused by the sheer forces encountered in the spinning process. The photoresist layer is then selectively exposed to radiation (e.g., ultraviolet radiation) with certain regions protected by a mask causing a chemical reaction (acid generation) in the exposed regions of the resist. The substrate is then subjected to a post-expose bake (PEB) during which the acid will diffuse and cause a chemical reaction that changes the solubility of the resist. During the development process, in which a photoresist developer is applied to the substrate, and the exposed photoresist undergoes dissolution (in a positive photoresist) leaving the unexposed photoresist behind. The substrate is then rinsed to remove the developer solution, and dried, for example by a spin-dry process.

One problem with conventional photolithography methods is that the desired resist pattern can collapse after the developer process, particularly during the spin-dry process when capillary forces are acting on the photoresist. As illustrated in FIG. 2, the capillary pressure gradients between structures (having a height H and a depth D) of a photoresist pattern 100 can cause the photoresist structure to collapse. Because the capillary forces (F) are inversely proportional to the spacing (S) between the photoresist structures, the problem of photoresist structure collapse is expected to become more significant as the spacing within the structure continues to shrink. Photolithography that involves exposure with radiation with wavelengths of near 13.5 nanometer (nm) wavelength, classified as extreme ultraviolet radiation (EUV), is expected to print structures with tight spacing or pitch (e.g., less than 100 nm), making resist collapse a significant problem.

Capillary forces can be alleviated by reducing the surface tension of the rinse solution, for example, by using surfactant-containing developer solutions. However, surfactants have been shown to introduce defects in the resist material. Furthermore, surfactants can reduce the surface tension only to a limited degree, and it is expected that as the pitch decreases to sub-100 nm dimensions, surfactants will not be effective in reducing collapse. Another method to prevent photoresist collapse is to reduce the surface tension by using super-critical CO₂ (SC CO2) for drying the resist structures. However, it is estimated that drying a resist using SC CO2 takes approximately 5 minutes, which adds significant processing time. Therefore, in order to obtain the throughput needed for high-volume manufacturing (HVM), multiple SC modules would be needed, which then adds significant cost to the manufacturing process.

### BRIEF DESCRIPTION OF THE DRAWINGS

Embodiments of the present invention are illustrated by way of example, and not limitation, in the figures of the accompanying drawings in which:

FIG. 1 is a flow chart of a typical photolithography process.

FIG. 2 illustrates the capillary pressure gradients between structures of a resist pattern that cause collapse.

FIG. 3 is a flowchart of one method to increase the mechanical strength of a photoresist material during a photolithography process.

FIG. 4A illustrates one embodiment of a structure prepared for a photolithography process to form a desired pattern, by defining a portion of a photoresist material to be removed.

FIG. 4B illustrates a photoresist developer applied to the photoresist layer of the structure of FIG. 4A.

FIG. 4C illustrates a configuration for rinsing the structure of FIG. 4A with a rinse solution.

FIG. 4D illustrates a second ultraviolet radiation treatment applied to the photoresist material after the structure of FIG. 4A is rinsed to remove the developer.

FIG. 4E illustrates the structure of FIG. 4A after the rinse solution has been dried off, with the photoresist material mechanically strengthened by the inducement of polymer cross-linking.

FIG. 5 is a flowchart of another method to increase the mechanical strength of a photoresist material during a photolithography process.

FIG. 6 illustrates a block diagram of one method of the present invention.

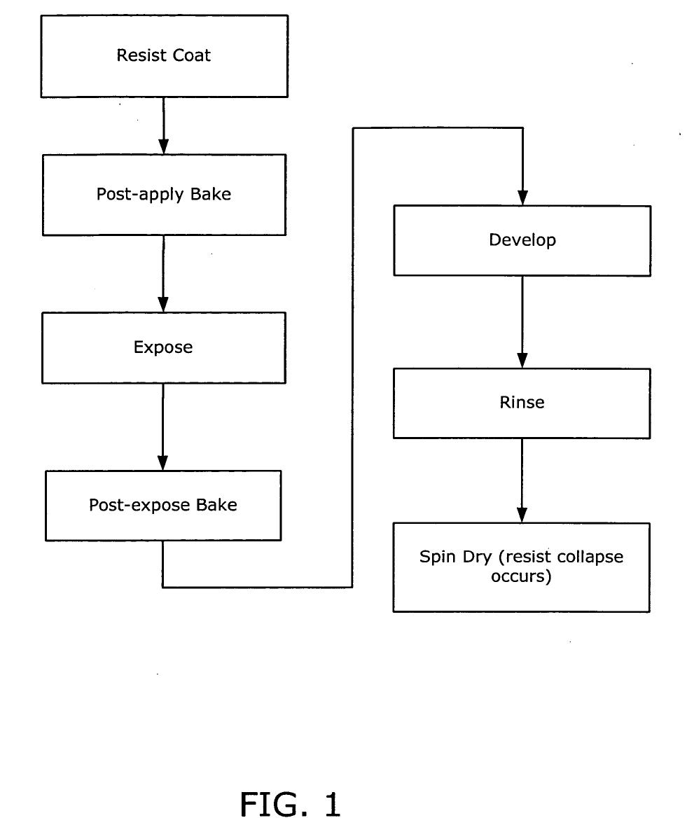

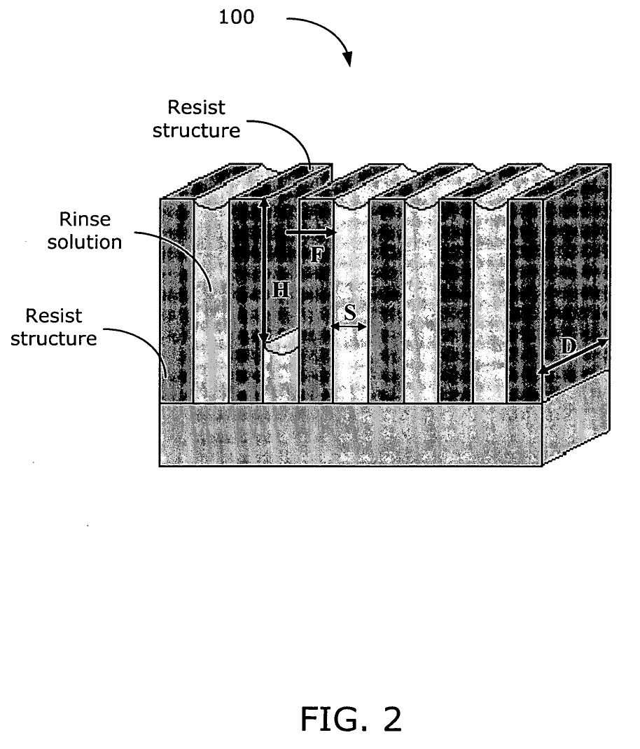

### DETAILED DESCRIPTION

In the following description, numerous specific details are set forth such as examples of specific materials or components in order to provide a thorough understanding of embodiments of the present invention. It will be apparent, however, to one skilled in the art that these specific details need not be employed to practice embodiments of the present invention. In other instances, well known components, methods, semiconductor equipment and processes have not been described in detail in order to avoid unnecessarily obscuring embodiments of the present invention.

Any reference in the specification to “one embodiment” or “an embodiment” means that a particular feature, structure, or characteristic described in connection with the embodiment is included in at least one embodiment of the claimed subject matter. The appearances of the phrase, “in one embodiment” in various places in the specification are not necessarily all referring to the same embodiment.

Embodiments of a method to improve the mechanical strength a photoresist pattern are described. In one embodiment, the polymers of the photoresist material are exposed, after a first exposure to radiation to form the latent image over and a developer solution, to a second radiation treatment to induce cross-linking. For example, after the photoresist material has been developed, but before the drying process to remove the rinse solution, the photoresist material is subjected to an ultraviolet radiation treatment to increase the amount of cross-linking of the polymer chains that compose the photoresist material. In an alternative embodiment, the rinse solution (applied after the developer solution) can include a cross-linking agent so that when applied over the patterned resist layer, the cross-linking agents penetrate the photoresist. Under flood exposure with another ultraviolet radiation treatment, the cross-linking agent further induces cross-linking of the resist material polymer chains. Inducing cross-linking of the photoresist material prevents collapse of the photoresist pattern formed during the photolithography process, particularly during the spin-dry process after a rinse solution is applied to remove the developer solution.

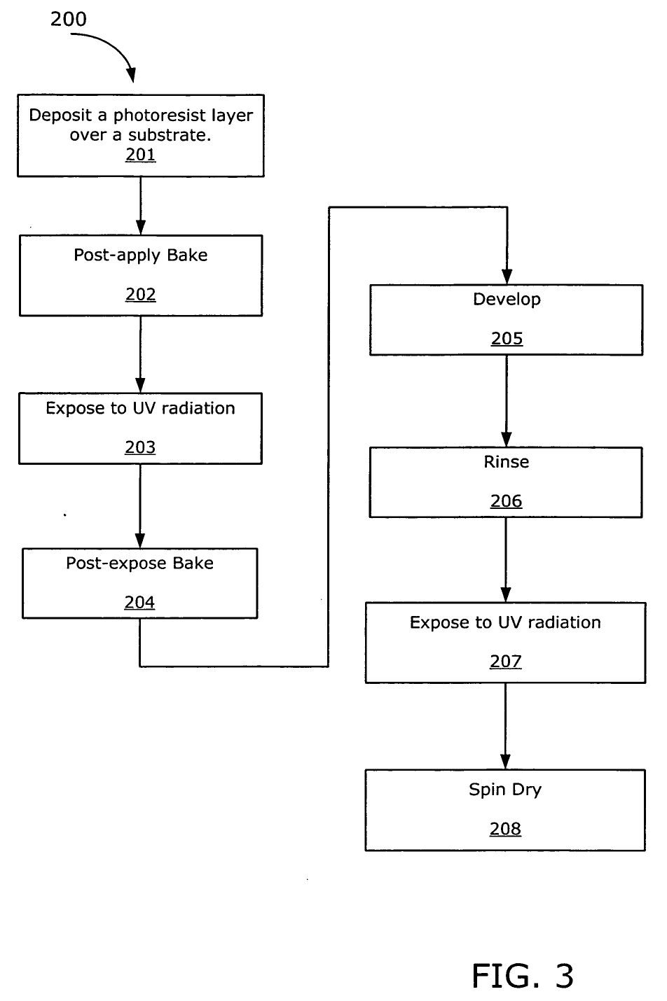

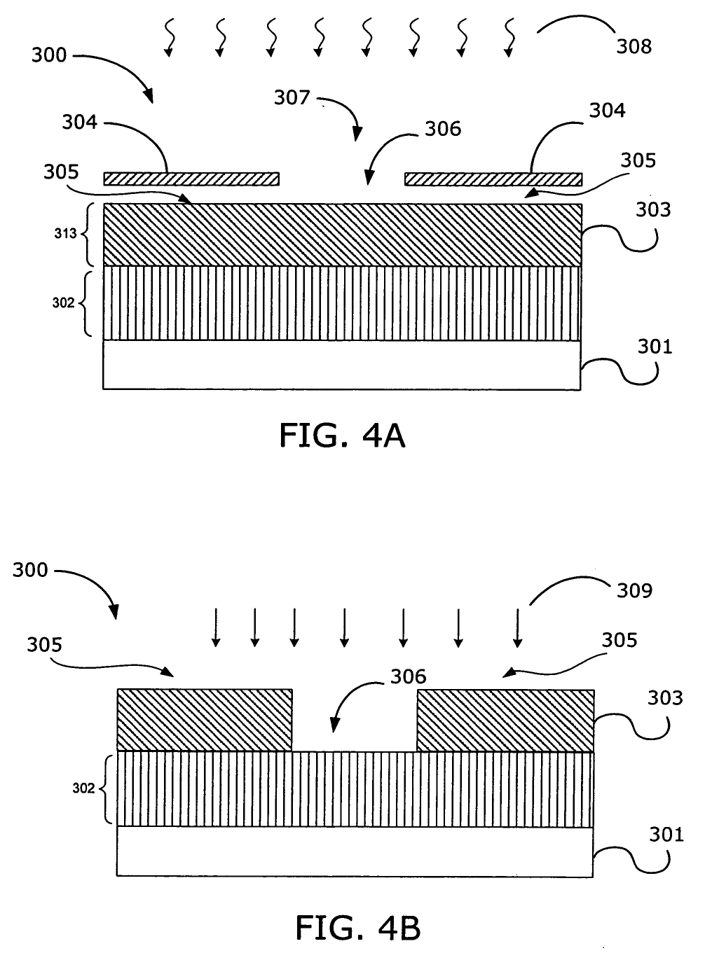

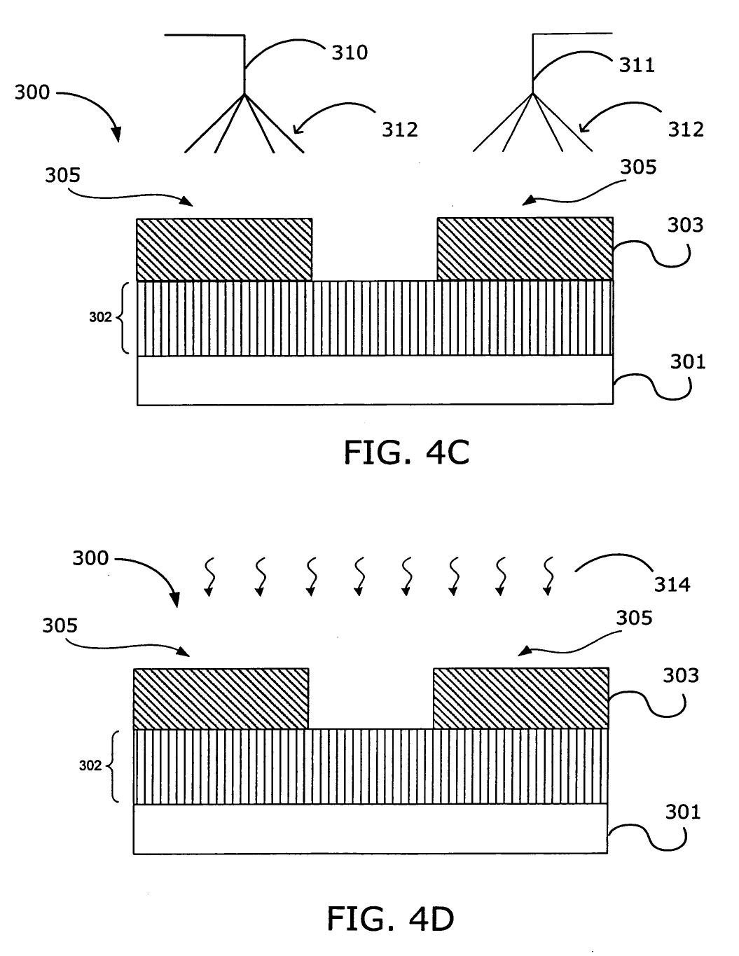

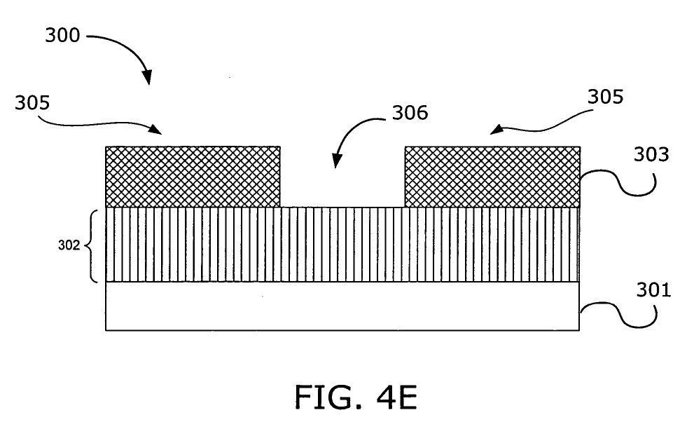

The flowchart of FIG. 3 and the structure of FIGS. 4A-4E, taken together, illustrate one embodiment of a method of a photolithography process to improve the mechanical strength of resist structures following development. In particular, FIGS. 4A-4E illustrate cross-sectional views of a partially processed circuit structure 300 undergoing a photolithography process in one embodiment of the present invention. Circuit structure 300 includes substrate 301 that may be a wafer substrate having circuit elements thereon, as well as one or more layers or levels of interconnection to circuit elements. Substrate 301 may also be a wafer upon which other manufacturing and processing operations may be performed so as to form various electrical components such as transistors. A dielectric material is deposited over substrate 301 to form dielectric layer 302. The dielectric layer 302 may be, for example, silicon dioxide (SiO₂) formed by a tetraethyl orthosilicate deposition process. Other suitable materials for the dielectric material may be contemplated, including materials having dielectric constants less than the dielectric constant of SiO₂ (e.g., “low k” materials), including polymers.

Although the terms “substrate”, “dielectric”, and “photoresist” are used herein, other terms may be used to describe the affected layers without departing from the intended scope of various embodiments of the invention. As used herein, the terms “above” and “below” refer to the orientation shown in the figures. The physical orientation (with respect to gravity) of an integrated circuit structure during fabrication may be different. The term “structure,” as used herein, refers collectively to the substrate and all existing layers at the indicated stage in the fabrication process, and to the physical elements in those layers that are being processed together. It is understood that FIGS. 4A-4E are not drawn to scale, and the relative dimensions of the physical structure should not be inferred from the relative dimensions shown in the drawings.

As illustrated in FIG. 4A, structure 300 is prepared for a photolithography process to form a desired pattern, by defining a portion of a photoresist material 303 to be removed. In one embodiment, the photolithography described herein relates to a positive photoresist methodology. The photoresist layer 313 is formed over substrate 301 and dielectric layer 302 by a spin coating process or other coating processes known in the art, in which the photoresist material 303 (in the form of a solution) is dispensed over a spinning substrate 301, block 201. The substrate then undergoes a post-apply bake process to remove excess solvent and relieve stresses caused by the sheer forces encountered in the spinning process, block 202. In one particular embodiment, forming photoresist layer 313 includes heating spreading the photoresist material 303 on the surface dielectric layer 302, spinning structure 300 at about 3,000 rpm for about 60 seconds to deposit photoresist material 303 to a thickness of about 150 nm, and heating structure 300 at about 115° C. for about 90 seconds to bake photoresist material 303. In one embodiment, photoresist material 303 can be a chemically amplified resist (CAR), or other types of positive tone resists known in the art. In an alternative embodiment, photoresist material 303 can be EUV resists, for example, acrylic polymer (such as acrylate, methacrylate, acrylate with a methyl group on the backbone, acrylate-methacrylate copolymers), cyclo-oelfin, phenolic based, silicon containing, or molecular glass based resins.

Following the post-apply bake process of photoresist material 303, mask 304 is aligned over structure 300, which defines opening 307 on mask 304 for exposure to radiation and encode an image in photoresist layer 313. Mask 304 may be, for example, any type of masking material known in the art. Having properly aligned mask 304 over structure 300, structure 300 is exposed to a radiation source, such as an ultraviolet radiation 308, block 203. In one embodiment, radiation from an ultraviolet light source passes through opening 307 of mask 304. Region 305 of photoresist material 303 is shielded by mask 304, preventing exposure to ultraviolet radiation 308. The radiation that passes through opening 307 contacts photoresist material 303 in region 306 exposed by opening 307 of mask 304. The light changes the chemical structure of photoresist material 303 in exposed region 306 from relatively non-soluble state to much more soluble state. In one embodiment, ultraviolet radiation having a wavelength between about 10 nm to about 250 nm can be applied to photoresist material 303. In one embodiment, photoresist material 303 that is a CAR resist is exposed to deep ultraviolet radiation (DUV) having a wavelength of about 248 nm. In another embodiment, the wavelength of radiation can be about 193 nm. In yet another embodiment, photoresist material 303 is exposed to extreme ultraviolet radiation (EUV) having a wavelength of about 13.5 nm. After exposure to the ultraviolet radiation, structure 300 undergoes a post-expose bake process, block 204. In chemically amplified photoresists, the effect of incident radiation is to generate a photoacid. The photoacid serves as a catalyst for deprotection reaction that occurs during the post-exposure bake (PEB) process. After PEB, deprotected regions can be removed easily during the developer process.

As illustrated in FIG. 4B, following PEB, a photoresist developer 309 is applied to photoresist layer 313 to remove the deprotected photoresist material 303 in region 306, block 205. Photoresist developer 309 retains the generally insoluble photoresist material over substrate 301 in region 305 that was not exposed to ultraviolet radiation from the ultraviolet source and/or areas in the bulk portion of photoresist material 303. In one embodiment, application of the developer 309 can involve immersing structure 300 in a solution of developer and water. For a positive-tone photoresist, a tetra methyl ammonium hydroxide (TMAH) aqueous solution is a developer that can enhance dissolution of the exposed photoresist material 303. Structure 300 is then rinsed to remove developer 309, block 206. FIG. 4C illustrates one embodiment of a configuration for rinsing structure 300 in which dispensers 310 and 311 spray a rinse solution 312 (e.g., DI water) over photoresist material 303. The rinse solution 312 can collect in the region of photoresist layer 313 that has been removed by developer 309 to expose the surface 302.

As illustrated in FIG. 4D, a second ultraviolet radiation treatment 314 is applied to photoresist material 303 after structure 300 is sufficiently rinsed to remove developer 309 but prior to spin-drying structure 300, block 207. This second ultraviolet radiation treatment 314 cures photoresist material 303, and induces cross-linking of the polymers/polymer chains comprising the photoresist material. In one embodiment of the present invention, the source of the second ultraviolet radiation treatment 314 can be DUV, EUV, or vacuum ultraviolet (VUV) radiation, for example, using deuterium, helium, or other discharge sources. The wavelength of the second ultraviolet radiation treatment 314 can be between about 10 nm to about 250 nm. For example, acrylic polymer, cyclo-oelfin, or phenolic based resins for photoresist material 303 can be exposed to a first ultraviolet radiation treatment having a wavelength of about 248 nm, 193 nm, or 13.5 nm prior to applying the developer solution. These examples of photoresist material 303 are then exposed to a second ultraviolet radiation treatment 313, after rinsing the developer but prior to drying structure 300, with DUV, EUV, VUV radiation, or radiation having a wavelength between about 10 nm to about 250 nm. For example, the DUV radiation can have a wavelength between about 100 nm to about 250 nm. In one particular embodiment, the second ultraviolet radiation treatment can have a wavelength of about 157 nm. Structure 300 is then dried with a spin-dry process to remove rinse solution 312, block 208. FIG. 4E illustrates structure 300 after the rinse solution 312 has been dried off, with photoresist material 303 mechanically strengthened by the inducement of polymer cross-linking. This provides the advantage of preventing photoresist collapse, particularly during the spin-dry process. The method described with respect to FIG. 3 and FIGS. 4A-4E can be performed in an integrated photolithography system that moves structure 300 from one tool to another tool automatically. For example, structure 300 can be moved along a wafer track from one processing tool (e.g., to form photoresist layer 313 over substrate 301) to another processing tool (e.g., to apply developer 309).

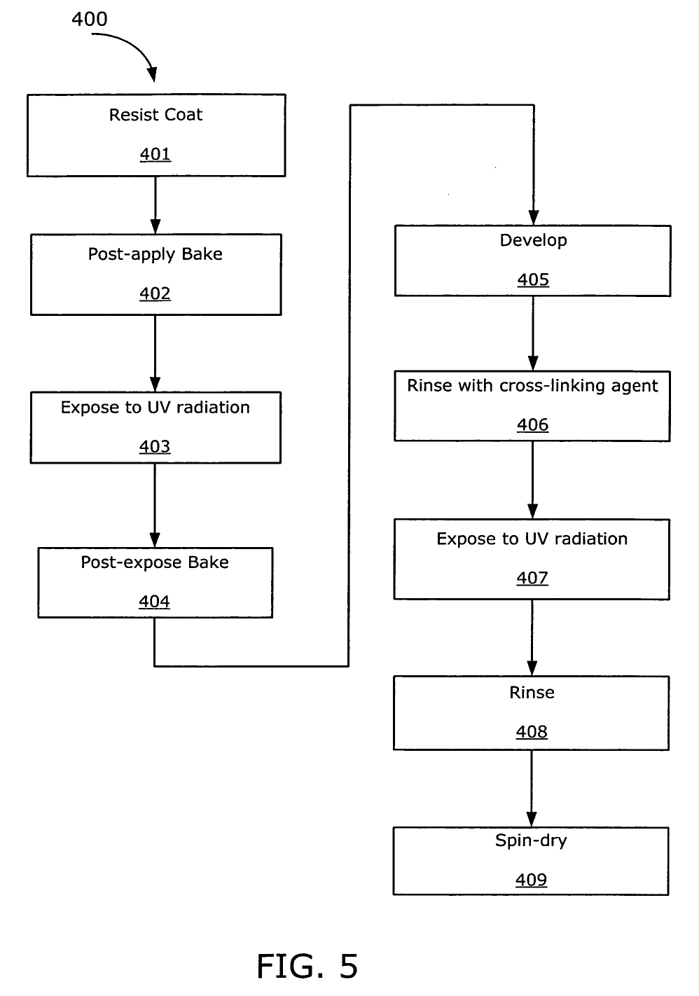

Flowchart 400 of FIG. 5 illustrates an alternative method to induce cross-linking of the photoresist material. Blocks 401-405 are analogous to blocks 201-205 described above with respect to flowchart 200 for the photolithography processes. After applying a developer to remove the exposed portions of photoresist material 303, structure 300 is rinsed with a rinse solution containing a cross-linking agent, block 406. For example, if any cross-linking occurs in photoresist material 303 before the photoresist pattern is developed, the contrast between the exposed and unexposed regions may be reduced, and resolution of the photoresist pattern may be reduced. By adding a cross-linking agent to the rinse solution, cross-linking of the photoresist material is further induced when exposed to ultraviolet radiation. In one embodiment of the present invention, the cross-linking agent can be vinyl ether or melamine cross-linkers, or other types of cross linking agents that are relatively small and have good solubility in aqueous solutions. When structure 300 is rinsed, the small organic cross-linking agents can penetrate photoresist material 303. When exposed to ultraviolet radiation, block 407, the cross-linking agent induces cross-linking to increase the mechanical strength of photoresist material 303. In one embodiment, the source of the second ultraviolet radiation treatment can be EUV, DUV or VUV radiation, for example, using deuterium, helium, or other discharge sources. The wavelength of the second ultraviolet radiation treatment can be between about 10 nm to about 250 nm. In one particular embodiment, the second radiation treatment can be DUV, with a wavelength between about 150 nm to about 250 nm. Optionally, structure 300 can be treated with a second rinse to remove any defects introduced from the presence of the cross-linking agents, block 408. Structure 300 is then dried with a spin-dry process to remove the rinse solution containing the cross-linking agent, block 409.

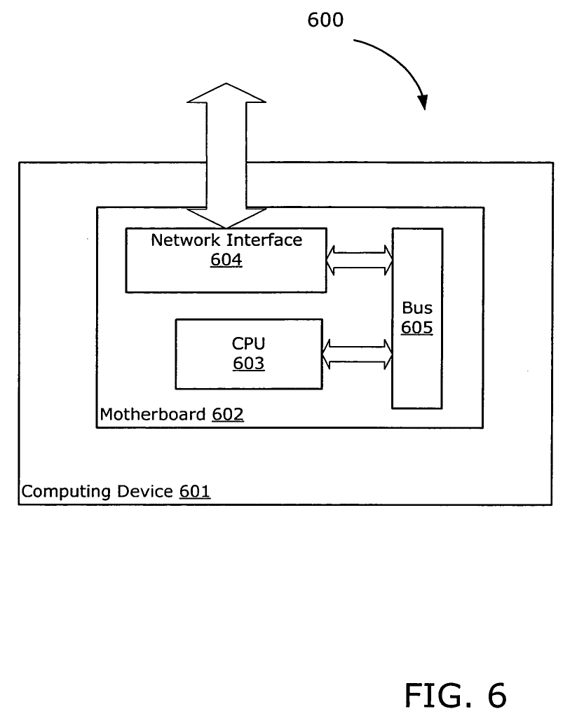

FIG. 6 illustrates a system 600 in accordance with one embodiment having structures or components formed by the methods described herein. As illustrated, for the embodiment, system 600 includes computing device 602 for processing data. Computing device 602 may include a motherboard 604. Motherboard 604 may include in particular a processor 606, and a networking interface 608 coupled to a bus 610. More specifically, processor 606 may comprise transistors or other circuit elements that have been formed by the earlier described photolithography methods.

In the foregoing specification, the invention is described with reference to specific embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

What is claimed is:

1. A method, comprising:
dispensing a photoresist material over a substrate to form a photoresist layer;
exposing the photoresist material to a first radiation treatment to define a pattern to be formed on the photoresist layer;
applying a developer solution to the photoresist material to form the pattern;
rinsing the substrate with a rinse solution to remove the developer solution; and
exposing the photoresist material to a second radiation treatment to induce cross-linking of the photoresist material.

2. The method of claim 1, wherein exposing the photoresist material to the second radiation treatment further comprises treating the photoresist material with a deep ultraviolet radiation source.

3. The method of claim 1, wherein exposing the photoresist material to the second radiation treatment further comprises treating the photoresist material with a vacuum ultraviolet radiation source.

4. The method of claim 1, further comprising drying the substrate after exposing the photoresist material to the second radiation treatment.

5. The method of claim 2, wherein the deep ultraviolet radiation source comprises a wavelength between about 100 nm to about 250 nm.

6. The method of claim 1, wherein the photoresist material comprises positive tone photoresist.

7. The method of claim 1, wherein the photoresist material comprises a chemically amplified photoresist.

8. The method of claim 1, wherein exposing the photoresist material to the first radiation treatment further comprises treating the photoresist material with an ultraviolet radiation source having a wavelength between about 10 nm to about 250 nm.

9. A method, comprising:
dispensing a photoresist material over a substrate to form a photoresist layer;
exposing the photoresist material to a first radiation treatment to define a pattern to be formed on the photoresist layer;
applying a developer solution to the photoresist material to form the pattern;
rinsing the substrate with a rinse solution comprising a cross-linker; and
exposing the photoresist material to a second radiation treatment to induce cross-linking of the photoresist material.

10. The method of claim 9, wherein the cross-linker comprises vinyl ether.

11. The method of claim 9, wherein the cross-linker comprises melamine.

12. The method of claim 9, wherein exposing the photoresist material to the second radiation treatment further comprises treating the photoresist material with a deep ultraviolet radiation source.

13. The method of claim 9, wherein exposing the photoresist material to the second radiation treatment further comprises treating the photoresist material with a vacuum ultraviolet radiation source.

14. The method of claim 9, further comprising drying the substrate after exposing the photoresist material to the second radiation treatment.

15. The method of claim 10, wherein the deep ultraviolet radiation source comprises a wavelength between about 100 nm to about 250 nm.

16. A method, comprising:
dispensing a photoresist material onto a substrate to form a photoresist layer;
placing a patterned mask between the radiation source and the photoresist layer;
exposing the photoresist material to a first ultraviolet radiation having a wavelength between about 10 nm to about 250 nm; and
applying a developer solution to the photoresist material; and
exposing the photoresist material to a second ultraviolet radiation having a wavelength between about 100 nm to about 250 nm, wherein the second radiation treatment induces cross-linking of the photoresist material.

17. The method of claim 16, further comprising spin-drying the substrate after exposing the photoresist material to the second radiation treatment.

18. The method of claim 16, wherein applying further comprise adding a cross-linking agent to the developer solution.

19. The method of claim 18, wherein the cross-linking agent comprises vinyl ether.

20. The method of claim 18, wherein the cross-linking agent comprises melamine.
